(19) United States
(12) Patent Application Publication
(10) Pub. No.: US 2008/0299729 A1
(43) Pub. Date: Dec. 4, 2008

(54) METHOD OF FABRICATING HIGH VOLTAGE MOS TRANSISTOR DEVICE

(76) Inventors: Wen-Fang Lee, Hsin-Chu City (TW); Yu-Hsien Lin, Kao-Hsiung City (TW); Ya-Huang Huang, Hsinchu City (TW); Ming-Yen Liu, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/754,357

(22) Filed: May 28, 2007

(51) Int. Cl. H01L 21/336

(52) U.S. Cl. 438/276; 438/289; 257/E21.409

(57) ABSTRACT

A substrate is provided, and a sacrificial pattern having an opening partially exposing a high voltage device region is formed on the substrate. Subsequently, a gate oxide layer is formed in the opening, and the sacrificial pattern is removed. A gate electrode, and two heavily doped regions are formed. Than, a salicidation process is carried out to form salicides on the surface of the gate electrode and the heavily doped regions.

### BACKGROUND OF THE INVENTION

1. Field of the Invention

The present invention relates to a method of fabricating high voltage MOS (HVMOS) transistor device, and more particularly, to a method of forming salicide without requiring forming salicide block (SAB) layer.

2. Description of the Prior Art

High voltage MOS transistor devices, e.g. double diffused drain (DDD) MOS transistor devices, are normally used in circuits that receive high voltage signals such as analogue IC or PMIC (power management IC).

Please refer to FIGS. 1-6. FIGS. 1-6 are schematic diagrams illustrating a conventional method of fabricating high voltage MOS transistor device. As shown in FIG. 1, a substrate 10 is provided. The substrate 10 includes a LVMOS region 12 and a HVMOS region 14, the LVMOS region 12 and the HVMOS region 14 are isolated by isolation structures 16.

As shown in FIG. 2, a low voltage gate oxide layer 18 is formed on the substrate 10 in the LVMOS region 12, and a high voltage gate oxide layer 20 is formed on the substrate 10 in the HVMOS region 14. Generally, the thickness of the low voltage gate oxide layer 18 is less than 200 angstroms, while the thickness of the high voltage gate oxide layer 20 is greater than 400 angstroms.

As shown in FIG. 3, a polycrystalline silicon layer 22 is deposited on the low voltage gate oxide layer 18 in the LVMOS region 12, and on the high voltage gate oxide layer 20 in the HVMOS region 14. Subsequently, photoresist masks 24, 26 are formed on the polycrystalline silicon layer 22, wherein the photoresist mask 24 is used to define the gate electrode's pattern in the LVMOS region 12, and the photoresist mask 26 is used to define the gate electrode's pattern in the HVMOS region 14.

As shown in FIG. 4, an etching process is performed to remove the polycrystalline silicon layer 22 not covered by the photoresist masks 24, 26 to form a gate electrode 28 in the LVMOS region 12 and a gate electrode 30 in the HVMOS region 14. The etching process is continued to etch the low voltage gate oxide layer 18 until the substrate 10 in the LVMOS region 12 is exposed.

As shown in FIG. 5, a photoresist layer is coated on the substrate 10, and photoresist masks 32, 34 are formed by a lithography process. The photoresist mask 32 blocks the LVMOS region 12, while the photoresist mask 34 covers the gate electrode 30 and a portion of the high voltage gate oxide layer 20 laterally protruding from the bottom of the gate electrode 30.

As shown in FIG. 6, an etching process is carried out to remove the high voltage gate oxide layer 20 not covered by the photoresist mask 34. Subsequently, the photoresist masks 32, 34 are removed.

The conventional method of fabricating a high voltage MOS transistor device requires an extra lithography and etching process to define the high voltage gate oxide layer in the HVMOS region, thereby increasing the complexity and manufacturing cost.

### SUMMARY OF THE INVENTION

It is therefore one objective of the claimed invention to provide a method of fabricating high voltage MOS transistor device to simplify process steps.

According to an embodiment of the claimed invention, a method of fabricating high voltage MOS transistor device is provided. A substrate having at least an HVMOS region is provided, and a sacrificial pattern is formed on the substrate. The sacrificial pattern has an opening partially exposing the HVMOS region. Subsequently, a gate oxide layer is formed on the substrate exposed by the opening. Then, the sacrificial pattern is removed, and a gate electrode is formed on the gate oxide layer. Following that, two heavily doped regions are formed in the substrate by both sides of the gate oxide layer, and salicides are formed on the surface of the gate electrode and on the surface of the two heavily doped regions.

The method of the present invention uses the opening of the sacrificial pattern to define the pattern of the gate oxide layer. Therefore, the method of the present invention does not require an extra lithography and etching process to define the pattern of the gate oxide layer. In addition, the salicide block layer is not required when forming the salicide, and thus manufacturing process is simplified.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic diagrams illustrating a conventional method of fabricating high voltage MOS transistor device.

FIGS. 7-15 are schematic diagrams illustrating a method of fabricating high voltage MOS transistor device according to a preferred embodiment of the present invention.

FIG. 16 is a schematic diagram illustrating a method of fabricating a high voltage MOS transistor device according to another embodiment of the present invention.

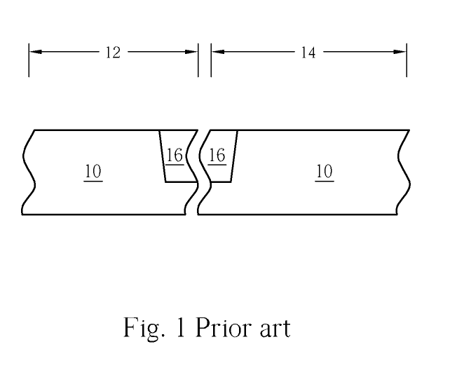

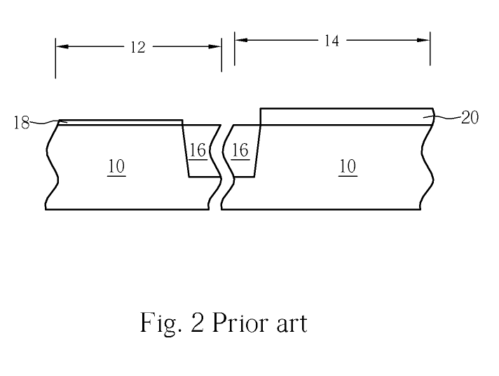

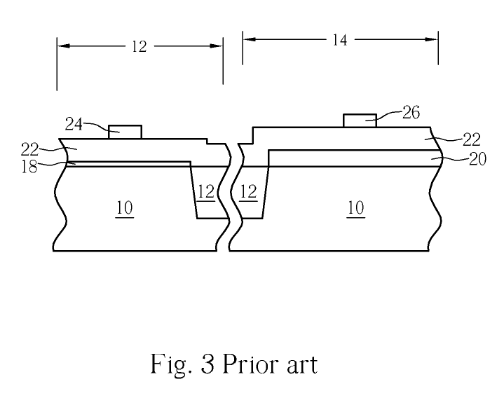

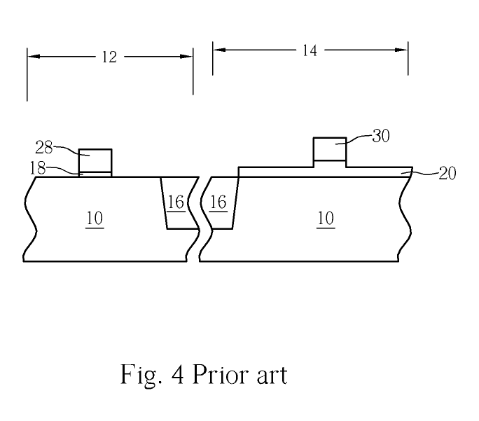

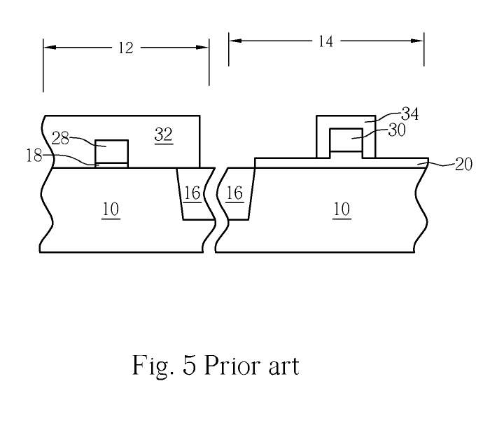

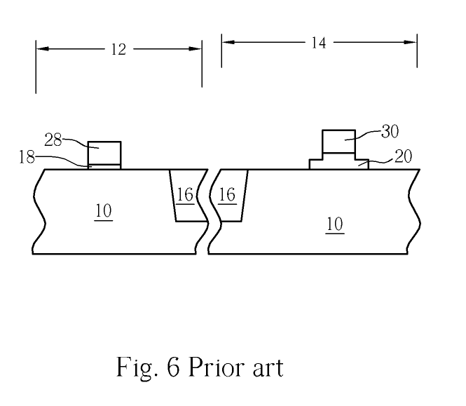

### DETAILED DESCRIPTION

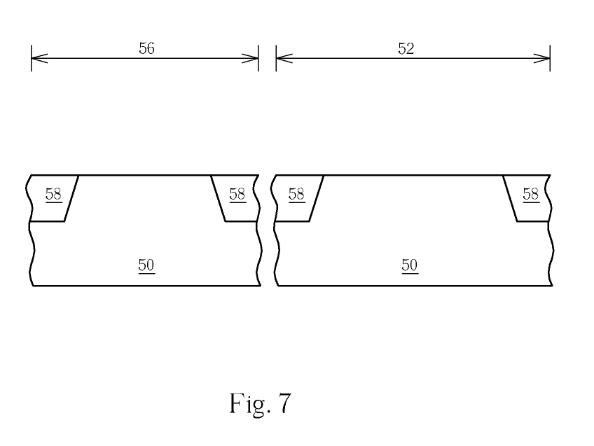

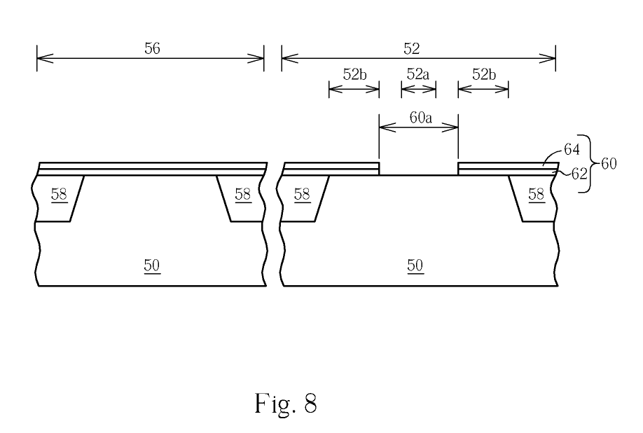

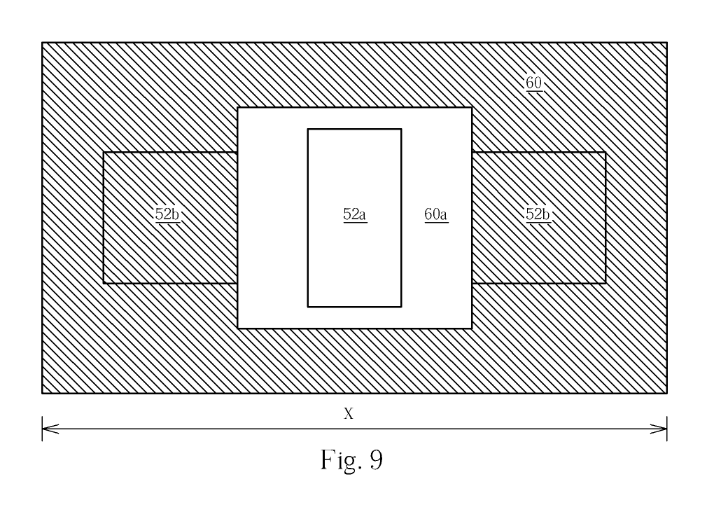

Please refer to FIGS. 7-15. FIGS. 7-15 are schematic diagrams illustrating a method of fabricating high voltage MOS transistor device according to a preferred embodiment of the present invention. This embodiment embodies an integrated method of forming high voltage devices and high voltage devices. However, the method of the present invention can be used to form high voltage devices separately, or can be integrated with other process e.g. medium voltage device fabrication. In the drawings, FIG. 9 is a top view of FIG. 8, and other Figures of this embodiment are cross-sectional views. As shown in FIG. 7, a substrate 50 e.g. a silicon wafer is provided. The substrate 50 includes at least an HVMOS region 52 an LVMOS region 56, and isolation structures 58 e.g. shallow trench isolations formed in the substrate 50 between the HVMOS region 52 and the LVMOS region 56.

As shown in FIGS. 8 and 9, the HVMOS region 52 has a gate electrode predetermined area 52a which defines the range of a gate electrode to be formed, and two heavily doped region predetermined areas 52b which define the range of source electrode and drain electrode to be formed. Then, a sacrificial pattern 60 having an opening 60a partially exposing the HVMOS region 52 is formed on the substrate 50. In the instant embodiment, the sacrificial pattern 60 includes a silicon oxide layer 62 and a silicon nitride layer 64, and the opening 60a is formed by removing a portion of the silicon oxide layer 62 and the silicon nitride layer 64 by photolithography and etching techniques. The silicon oxide layer 62 is formed to release the stress between the silicon nitride layer 64 and the substrate 50, and the silicon oxide layer 62 may be omitted. In other embodiments, other materials can be used to form the sacrificial pattern 60. It is to be appreciated that in the channel direction of gate electrode (X direction shown in FIG. 9), the length of the opening 60a of the sacrificial pattern 60 is larger than the length of the gate electrode predetermined region 52a, which equals the length of the gate electrode to be formed. The length of the opening 60a is substantially equal to the distance between the to heavily doped region predetermined regions 52b.

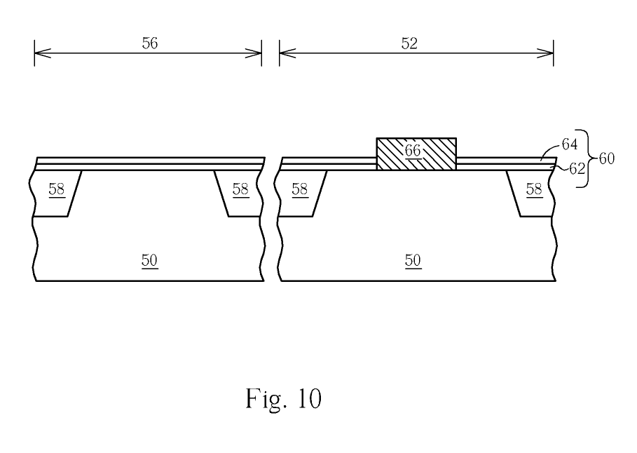

As shown in FIG. 10, a thermal oxidation process is performed to form a first oxide layer 66 on the surface of the substrate 50 exposed through the opening 60a of the sacrificial pattern 60 in the HVMOS region 52. The first oxide layer 66 is used to form a high voltage gate oxide layer, but the thickness of the high voltage gate oxide layer is the sum of the first oxide layer 66 and the thickness of a second oxide layer, which serves as a low voltage gate oxide layer, to be formed. The thickness of the high voltage gate oxide layer can be varied to satisfy different application. Generally, the thickness of the high voltage gate oxide layer is over 400 angstroms. In this embodiment the thickness is substantially 760 angstroms, but not limited to.

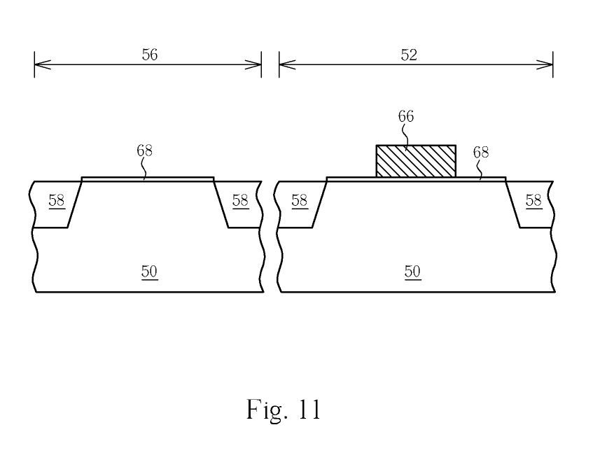

As shown in FIG. 11, the sacrificial pattern 60 is removed. Subsequently, another thermal oxide process is performed to form a second oxide layer 68 on the substrate 50. The second oxide layer 68 is disposed on the surface of the substrate 50 in the LVMOS region 56 and in between the first oxide layer 66 and the substrate 50 in the HVMOS region 52. The second oxide layer 68 disposed in the LVMOS region 56 is used to form a low voltage gate oxide layer, and the second oxide layer 68 and the first oxide layer 66 disposed in the HVMOS region 52 are used to form the high voltage gate oxide layer. In the present embodiment, the thickness of the low voltage gate oxide layer is approximately 40 angstroms, and the thickness of the high voltage gate oxide layer is equal to the sum of the thickness of the first oxide layer 66 and the second oxide layer 68.

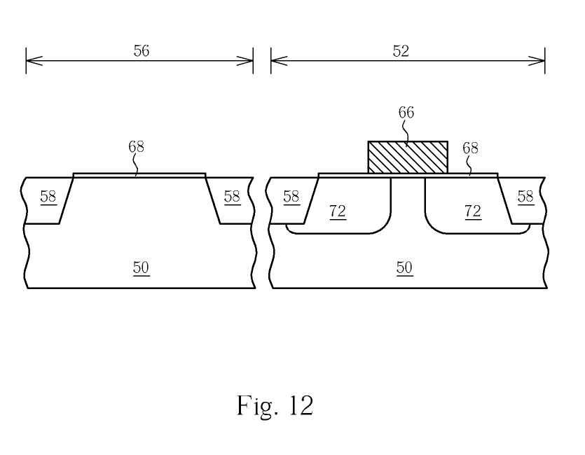

As shown in FIG. 12, an implantation process is carried out using a mask pattern (not shown) to form two lightly doped regions 72 in the substrate 50 by both sides of the high voltage gate oxide layer in the HVMOS region 52. In this embodiment, an N type high voltage device is to be formed, and thus the lightly doped regions 72 are N type. If a P type high voltage device is required, the lightly doped regions 72 should be P type.

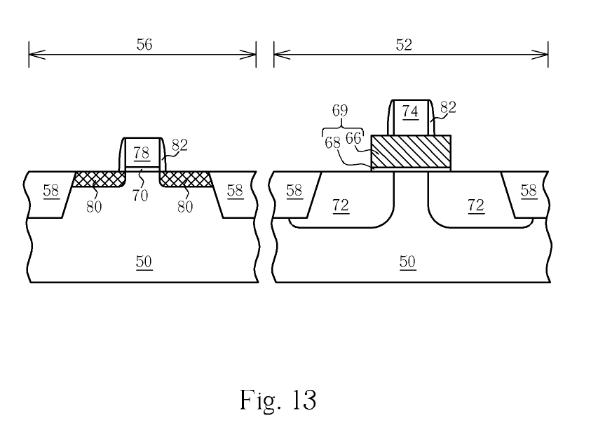

As shown in FIG. 13, a deposition process is performed to form a polycrystalline silicon layer (not shown) on the second oxide layer 66. The polycrystalline silicon layer is then etched using a mask pattern (not shown) to form gate electrodes 74, 78 respectively in the HVMOS region 52 and in the LVMOS region 56. Subsequently, an etching process is performed using the gate electrodes 74, 78 as hard masks to remove the second oxide layer 68 not covered by the gate electrodes 74, 78 to form a low voltage gate oxide layer 70 in the LVMOS region 56, and a high voltage gate oxide layer 69 in the HVMOS region 52. It is appreciated that the thickness of the first oxide layer 66 is much greater than that of the second oxide layer 68. Therefore the etched portion of the first oxide layer 66 disposed by both sides of the gate electrode 74 can be ignored, and not shown in FIG. 13. Then, lightly doped drains 80 are formed in the LVMOS region 56, and spacers 82 are formed alongside the gate electrodes 74, 78.

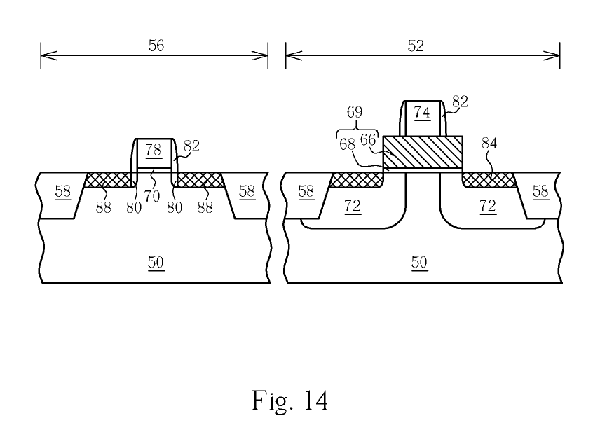

As shown in FIG. 14, an implantation process is performed using a mask pattern (not shown) to respectively form two heavily doped region 84, 88 in the substrate 50 by both sides of the gate electrodes 74, 78. The lightly doped regions 84, 88 respectively serve as the source/drain electrodes of the high voltage device and low voltage device. In this embodiment, the heavily doped regions 84 in the HVMOS region 52 are N type, and the heavily doped regions 84 and the lightly doped regions 72 form double diffused drains.

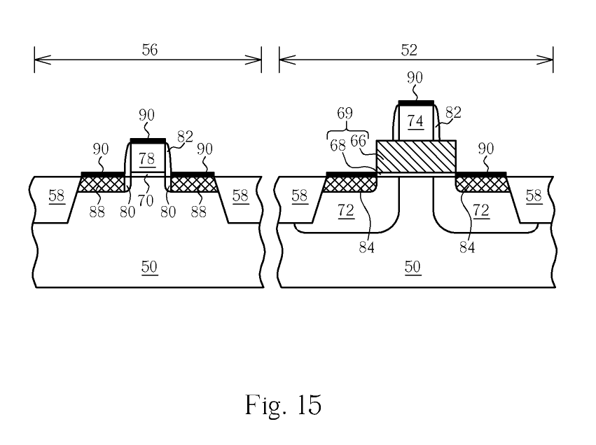

As shown in FIG. 15, a salicidation process is performed to form salicide 90 on the surface of the gate electrode 74, 78, and on the surface of the heavily doped regions 84, 88.

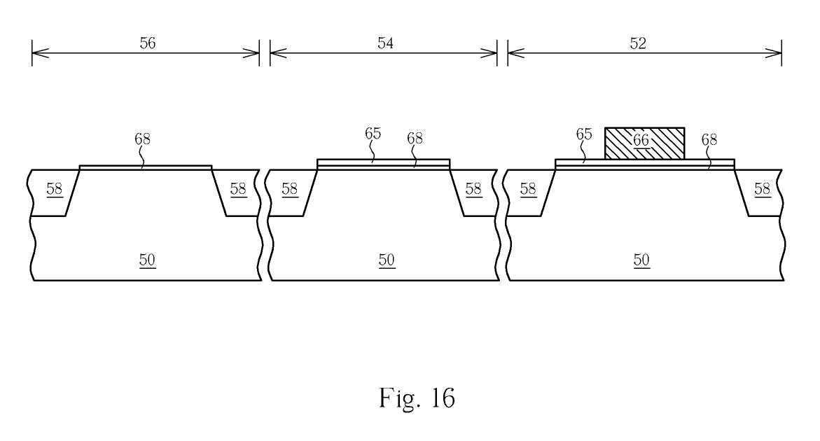

The method of the present invention is not limited by the aforementioned embodiment. For instance, the method of the present invention can be integrated with the medium voltage device fabrication. Please refer to FIG. 16. FIG. 16 is a schematic diagram illustrating a method of fabricating a high voltage MOS transistor device according to another embodiment of the present invention. For comparing these two embodiments, like parts are denoted by like numerals, and only the different parts are illustrated. As shown in FIG. 16, the substrate 50 further includes a MVMOS region 54 in addition to the HVMOS region 52 and the LVMOS region 56. In this embodiment, a third oxide layer 65 is formed on the substrate 50 in the MVMOS region 54 and in the HVMOS region 52 prior to forming the second oxide layer 68. The third oxide layer 65 and the second oxide layer 68 together form the medium voltage gate oxide layer in the MVMOS region 54, and the third oxide layer 65, the second oxide layer 68 and the first oxide layer 66 are used to form the high voltage gate oxide layer.

The method of the present invention uses the opening of the sacrificial pattern to define the pattern of the high voltage gate oxide layer. Therefore, the method of the present invention does not require an extra lithography and etching process to form the high voltage gate oxide layer. In addition, the method of the present invention does not require forming the salicide block layer when forming the salicide, and thus manufacturing process is simplified.

Those skilled in the art will readily observe that numerous modifications and alterations of the device and method may be made while retaining the teachings of the invention.

What is claimed is:

1. A method of fabricating high voltage MOS transistor device, comprising:
providing a substrate having at least an HVMOS region;
forming a sacrificial pattern on the substrate, the sacrificial pattern having an opening partially exposing the HVMOS region;
forming a gate oxide layer on the substrate exposed by the opening;
removing the sacrificial pattern;
forming a gate electrode on the gate oxide layer;
forming two heavily doped regions in the substrate by both sides of the gate oxide layer; and
forming a salicide on the surface of the gate electrode and on the surface of the two heavily doped regions.

2. The method of claim 1, wherein the sacrificial pattern comprises a silicon nitride layer.

3. The method of claim 2, wherein the sacrificial pattern further comprises a silicon oxide layer disposed between the silicon nitride layer and the substrate.

4. The method of claim 1, further comprising forming two lightly doped regions in the substrate prior to forming the gate electrode on the gate oxide layer in the HVMOS region.

5. The method of claim 4, wherein each light doped region and the heavily doped region corresponding to the light doped region form a double diffused drain.

6. The method of claim 1, wherein the two heavily doped regions are a source electrode and a drain electrode.

7. The method of claim 1, wherein the gate oxide layer in the HVMOS region is formed by a thermal oxidation process.

8. The method of claim 1, wherein the length of the opening of the sacrificial pattern is larger than the length of the gate electrode in a channel direction of the gate electrode.

9. The method of claim 1, further comprising forming an isolation structure in the substrate prior to forming the sacrificial pattern.

10. A method of fabricating high voltage MOS transistor device, comprising:
providing a substrate having an HVMOS region and an LVMOS region;
forming a sacrificial pattern on the substrate, the sacrificial pattern having an opening partially exposing the HVMOS region;
forming a first oxide layer on the substrate exposed by the opening;
removing the sacrificial pattern;
forming a second oxide layer on the substrate, the second oxide layer covering the first oxide layer;
forming a gate electrode on the second oxide layer in the HVMOS region and a gate electrode on the second oxide layer in the LVMOS region;
removing the second oxide layer not covered by the gate electrode of the LVMOS region to form a low voltage gate oxide layer, and removing the second oxide layer not covered by the gate electrode of the HVMOS region to form a high voltage gate oxide layer;
forming two heavily doped regions in the substrate by both sides of the high voltage gate oxide layer; and
forming a salicide on the surface of the gate electrode and on the surface of the two heavily doped regions in the HVMOS region.

11. The method of claim 10, wherein the sacrificial pattern comprises a silicon nitride layer.

12. The method of claim 11, wherein the sacrificial pattern further comprises a silicon oxide layer disposed between the silicon nitride layer and the substrate.

13. The method of claim 10, further comprising forming two lightly doped regions in the substrate in the HVMOS region prior to forming the gate electrode on the second oxide layer in the HVMOS region.

14. The method of claim 13, wherein each light doped region and the heavily doped region corresponding to the light doped region form a double diffused drain.

15. The method of claim 10, wherein the two heavily doped regions are a source electrode and a drain electrode.

16. The method of claim 10, wherein the high voltage gate oxide layer in the HVMOS region is formed by a thermal oxidation process.

17. The method of claim 10, wherein the second oxide layer is formed by a thermal oxidation process.

18. The method of claim 10, wherein the thickness of the high voltage gate oxide layer is substantially equal to a sum of the thickness of the first oxide layer and the thickness of the second oxide layer.

19. The method of claim 10, wherein the length of the opening of the sacrificial pattern is larger than the length of the gate electrode in a channel direction of the gate electrode in the HVMOS region.

20. The method of claim 10, further comprising forming isolation structures in the substrate prior to forming the sacrificial pattern.
